(19) United States
(12) Patent Application Publication
(10) Pub. No.: US 2026/0332092 A1
(43) Pub. Date: Oct. 22, 2026

(54) BREAKPOINT DETECTION DEVICE BASED ON BI-DIRECTIONAL DETECTION AND USE METHOD OF BREAKPOINT DETECTION DEVICE

(71) Applicant: NANTONG UNIVERSITY, Nantong (CN)

(72) Inventors: Qiang WANG, Nantong (CN); Xiangan SUN, Nantong (CN); Jia CHEN, Nantong (CN); Baochen LIAO, Nantong (CN); Yuhang HUANG, Nantong (CN); Jie DENG, Nantong (CN); Jiangning GAO, Nantong (CN)

(21) Appl. No.: 18/837,640

(22) PCT Filed: Apr. 18, 2024
(86) PCT No.: PCT/CN2024/088593

§ 371 Date: Jul. 7, 2026

(30) Foreign Application Priority Data
Apr. 26, 2023 (CN) 202310463354.9

(51) Int. Cl. H02S 50/10; G01R 19/25

(52) U.S. Cl. CPC H02S 50/10; G01R 19/25

(57) ABSTRACT

A breakpoint detection device based on bi-directional detection and a use method of the breakpoint detection device are provided. The breakpoint detection device includes second supports, first supports, support beams and sensor device. Tops of the second supports are connected with the first supports. Screws penetrate through inner walls of the support beams. An outer wall of each screw is provided with a buckle belt. An inner wall of the buckle belt is provided with the sensor device. The sensor device includes a top cover, a first plug, a first spring, an insulation joint and a baffle plate. The baffle plate is arranged inside the sensor device.

### CROSS-REFERENCE TO RELATED APPLICATION

This application is a national stage application of International Patent Application No. PCT/CN2024/088593 filed on Apr. 18, 2024, which application claims the benefit and priority of Chinese Patent Application No. 202310463354.9 filed with the China National Intellectual Property Administration on Apr. 26, 2023, and entitled “breakpoint detection device based on bi-directional detection and use method of breakpoint detection device”. The two applications are incorporated by reference herein in the entirety as part of the present application.

### TECHNICAL FIELD

The present disclosure relates to the technical field of photovoltaic power station safety protection, in particular to a breakpoint detection device based on bi-directional detection and a use method of the breakpoint detection device.

### BACKGROUND

At present, there is relatively little research on the detection and identification of bolted connection state of photovoltaic modules all over the world, and the existing methods for detecting bolted connection looseness mainly include the following methods: (1) manual inspection method; (2) a method based on piezoelectric smart material technology; (3) a method based on acoustic emission technology.

The earliest and most effective detection method is the manual inspection method. The operation and maintenance personnel regularly inspect all photovoltaic modules of the distributed photovoltaic power station to check whether the connecting bolts of the parts are tightened. This detection method is extremely low in efficiency and high in labor cost.

The method based on piezoelectric smart material technology is a relatively common method for bolt looseness identification and detection. According to the method, whether the bolts are loosened or not is identified with the direct and inverse piezoelectric effects of piezoelectric materials. However, due to the difference of pretension force of each worker during construction, and the pretension force cannot be effectively predicted, so the method cannot be used in the actual process. The detection method with piezoelectric materials also causes the system connection to become very complicated, resulting in high cost.

According to the principle of acoustic emission detection, elastic waves emitted by the acoustic emission source are propagated to the surface of the material, resulting in the mechanical vibration of the material. And then, the mechanical vibration of the material is converted into an electrical signal by the acoustic emission detector for data processing, and the performance of the material is analyzed and deduced from the signal. The identification and extraction process of structural dynamic parameters are often based on the assumption of linearization, and many important nonlinear vibration effects are ignored. Therefore, damage information such as the loosening position and loosening degree of a single bolt is difficult to accurately identify and locate according to the relevant methods based on structural dynamic parameter analysis, and the frequency information extracted by acoustic emission is easily submerged under complex noise environment frequencies, so the method cannot be put into practical application.

### SUMMARY

The purpose of the present disclosure is to provide a breakpoint detection device based on bi-directional detection and a use method of the breakpoint detection device so as to solve the technical problem proposed in the above background that the existing manual scheduled maintenance in a photovoltaic power station is low in efficiency of screw loose.

In order to achieve the purpose, the present disclosure provides the following scheme: A breakpoint detection device based on bi-directional detection includes:

second supports, wherein tops of the second supports are connected with first supports, tops of the first supports are symmetrically connected with support beams, and tops of the support beams are sequentially provided with photovoltaic panels and blank holders in a staggered manner.

Screws penetrate through inner walls of the support beams, an outer wall of each screw is provided with a buckle belt, and an inner wall of the buckle belt is provided with a sensor device.

The sensor device includes a top cover, a first plug, a first spring, an insulation joint and a baffle plate. The baffle plate is arranged inside the sensor device. One end of the first spring is fixedly connected with an outer wall of the baffle plate. A round hole is formed in an inner wall of the baffle plate. The first plug penetrates through an inner wall of the round hole. One end of the first plug is connected with the insulation joint. One end of the sensor device is provided with the top cover.

Preferably, the buckle belt includes a circular slot and a column plug. The circular slot is formed in an interior of the buckle belt. The column plug penetrates through an interior of the circular slot, and one end of the column plug is fixedly connected with an outer wall of the buckle belt.

Preferably, a nut is mounted around the outer wall of the screw, and the nut is located below the buckle belt. The outer wall of the screw is symmetrically provided with a first gasket and a second gasket, the outer wall of the buckle belt is connected with an outer wall of the second gasket. A second spring is arranged between the first gasket and the second gasket.

Preferably, a square notch is formed in an outer wall of the sensor device. The outer wall of the sensor device is provided with a first thread line, and the first thread line is located on one side of the square notch. The outer wall of the sensor device is provided with a second thread line, and the second thread line is located on one side of the first thread line. An outer wall of the second thread line is provided with a bottom cover. A first wire outlet and a second wire outlet are symmetrically formed in an outer wall of the bottom cover. An inner wall of the sensor device is provided with a metal sheet, and the metal sheet is located on one side of the baffle plate. A lead wire port is formed in an outer wall of the metal sheet. A socket is formed in the outer wall of the metal sheet, and one end of the insulation joint extends to the interior of the socket. The inner wall of the sensor device is provided with a partition plate. An outer wall of the first thread line is provided with a rotating circular ring.

Preferably, the sensor device is in a shape of a hollow column and is embedded in the buckle belt. The column plug is cylindrical in shape. An outside dimension of the column plug is equal to an inside dimension of the circular slot. The first gasket and the second gasket are disc-shaped in shape. The metal sheet and the partition plate are both disc-shaped. Dimensions of the metal sheet and the partition plate are equal to an inside dimension of the sensor device. A side surface of the first plug is fixedly connected with a wire which penetrates through the round hole of the baffle plate and the lead wire port of the metal sheet and finally is led out through the first wire outlet of the bottom cover. One end of the metal sheet is also connected with a wire which is led out through the second wire outlet of the bottom cover.

Preferably, an outer wall of each second support is provided with a box. The box includes a relay, a digital potentiometer, a single-chip microcomputer and a wireless transmission module. The relay, the digital potentiometer, the single-chip microcomputer and the wireless transmission module are all arranged inside the box and electrically connected. A heat emission hole is formed in an outer wall of the box.

A use method of the breakpoint detection device based on bi-directional detection. A implementation method of the breakpoint detection based on bi-directional detection includes the following steps: a first step1: sensor network design, including sensor design, detection design of loosened screws of photovoltaic modules at different positions, and sensor network connection design; a second step: forward voltage detection to position loosened photovoltaic modules; a third step, reverse voltage detection to judge a number of breakpoints of the loosened photovoltaic modules; a fourth step, traversal algorithm design.

A sensor in the first step is composed of the screw, the nut, gaskets, a spring and a hoop side pressure sensor. The first gasket, the second spring and the second gasket are placed on the screw in sequence. The nut is tightened along a thread line. A surface of the second spring is completely pressed into a plane. The second gasket is wrapped with the buckle belt of a hoop side pressure device, and the circular slot is tightly buckled with the column plug. At this time, the top cover of the sensor device directly faces the first gasket and is extruded outwards by the first gasket. A displacement of the top cover drives the connected first plug and first spring to push inwards, so that the first plug penetrates through the round hole inside the baffle plate. When the sensor device is completely covered with the top cover, the insulation joint at a rightmost end of the first plug is completely inserted into the socket of the metal sheet. At this time, a front end surface of the first plug is completely laminated to the metal sheet to form a conducting loop, so that the sensor is in a low-resistance state. When the screw is loosened, the second spring is restored. The first gasket and the second gasket are bounced off by force. The top cover of the sensor device is not extruded by the second spring any more. The first spring connected with the top cover is restored to push the top cover to displace towards the direction of the screw. A displacement of the top cover drives the first plug to displace towards the direction of the screw at a same time. The insulation joint on a top of the first plug drives the metal sheet to move for a certain distance and is blocked and separated by the partition plate. At this time, the front end surface of the first plug is not in contact with the metal sheet any more, and the conducting loop becomes a disconnected loop, so that the sensor is in a high-resistance state.

For a loop side pressure device in the first step, when the screw is loosened, the insulation joint on the top of the first plug drives the metal sheet to move for the certain distance, so that a certain travel is provided for detecting a tightened state to a loosened state by the sensor. The baffle plate can be controlled to move forward (reverse) by the rotating circular ring, so that the baffle plate drives the first spring to move forward (reverse) so as to achieve the purpose of controlling a protrusion angle of the top cover. A distance between the metal sheet and the bottom cover is controlled by rotating the bottom cover so as to ensure that the insulation joint of the first plug can be completely pushed into the socket of the metal sheet when the top cover is completely extruded by the first spring.

For the detection design of loosened screws of photovoltaic modules at different positions in the first step, the screws of a distributed photovoltaic power station are distributed in two types of positions, including screws fixed on boards and screws fixed between supports. The screws fixed on board on one photovoltaic module are mainly distributed at four corners. All screws at a same corner are taken as one sensor, and four sensors are shared on a same photovoltaic module. When at least one edge is adjacent between the adjacent photovoltaic modules, two screws are shared on an adjacent edge to fix upper and lower corners, two sensors are shared on each adjacent edge, and 2N+2 sensors are needed for the screws fixed on boards on N photovoltaic modules. When the screws fixed between supports on the N photovoltaic modules are divided into M groups, the screws fixed at a same corner of each support are taken as one sensor.

For a feature recognition method of loosened screws of photovoltaic modules at different positions, every n sensors are serially connected together, and a coding resistance with a resistance value of Rᵢ is connected at both ends in parallel as a feature for detecting the looseness of board screws. In the first step, wires at both ends of the sensor are connected with a wire with a diode string resistance value of rᵢ as a feature for detecting a number of screws fixed on boards. In the first step, the wires of the sensor are respectively connected with two diodes and a resistance with a resistance value of a in parallel as a feature for detecting screws fixed between the supports. For the sensor network connection design in the first step, a negative electrode in each sensor in the photovoltaic modules is connected with a positive electrode of a next sensor through a wire, every n sensors are serially connected together, and the coding resistance with the resistance value of Rᵢ is connected at both ends in parallel. As a sensor branch, a wire is led out at a negative electrode of each sensor branch to be connected with a positive electrode of a next sensor branch, and all sensor branches are serially connected to form a sensor network.

For the forward voltage detection in the second step, two forward voltages are applied to the N photovoltaic modules by a power source. When all screws on the N photovoltaic modules are tightened, the sensor network is in a low-resistance state, all coding resistances Rᵢ are all short-circuited, and an overall resistance value of the N photovoltaic modules measured by the two forward voltages is just an internal resistance of wires. When equivalent resistance values measured by the two forward voltages are same, but extremely larger than the internal resistance of the wires, it is indicated that breakpoints appear at joints of the boards of the photovoltaic modules (the screws are loosened). Corresponding sensors are in the high-resistance state, and a detected equivalent resistance of the N photovoltaic modules is a sum of the corresponding coding resistances Rᵢ and the internal resistance of the wires. When the equivalent resistance values measured by the two forward voltages are different, it is indicated that breakpoints appear at joints of the supports of the photovoltaic modules, corresponding sensors are in the high-resistance state, and ae difference between two detected equivalent resistances of the N photovoltaic modules is a sum of the corresponding coding resistances ai and the internal resistance of the wires.

Through the forward voltage detection in the second step, precision positioning for the loosened photovoltaic modules can be realized. According to a contrast between the equivalent resistance and the coding resistances Rᵢ or ai, breakpoints at the joints of the boards or at the joints of the supports can be distinguished.

For the reverse voltage detection in the third step, when breakpoints appear at the joints of the boards of the photovoltaic modules in the third step, two different reverse voltages are applied to the N photovoltaic modules to measure two current values, and a resistance value is obtained through a formula

$$r = \frac{Δ U}{Δ I}$$

to be contrasted with the coding resistances rᵢ so as to judge a number of the breakpoints of the loosened photovoltaic modules.

Power switching between forward voltages and reverse voltages in the second step and the third step is realized by controlling two relays by the single-chip microcomputer.

For supplies of two different voltages in the second step and the third step, the digital potentiometer and the sensor network formed by the N photovoltaic modules are serially connected. Voltages are applied forward and reverse for a whole circuit by the power source, and different partial voltages for the sensors can be realized by changing a programmable resistance value in the digital potentiometer.

For the traversal algorithm design in the fourth step, a superposition of various different coding resistances may result in a same resistance result respectively detected by the forward voltages in the second step and the reverse voltages in the third step, thus various possible reasons corresponding to the same resistance result detected by the forward voltages and various possible reasons corresponding to the same resistance result detected by reverse voltages respectively need to be recognized through traversal algorithm, and an intersection of possible reasons is taken to achieve a purposes of positioning the loosened photovoltaic modules and detecting the number of the breakpoints.

A fifth step, maintenance condition judgment. Maintenance conditions are as follows: (1) when breakpoints exist on two of the four corners of a certain photovoltaic module, the loosened photovoltaic module needs to be maintained; and (2) when one breakpoint exists on all unadjacent photovoltaic modules, all photovoltaic modules with the breakpoint need to be maintained.

the photovoltaic modules are divided into M groups, and every N photovoltaic modules form one group; M pin ports of the single-chip microcomputer are respectively connected with M groups of circuits through the single-chip microcomputer, and the M groups of circuits are arranged in a shape of a star; the single-chip microcomputer is placed in a center of the star; a transmission rate of signals is increased; and a state information of all screws on M×N photovoltaic modules can be collected by one single-chip microcomputer, so that a production cost is reduced.

Compared with the prior art, the present disclosure has the following beneficial effects:

Firstly, the single-chip microcomputer and the sensor device are mounted, so that the problem that the existing manual scheduled maintenance in a photovoltaic power station is low in efficiency of screw loose is solved. Forward and reverse resistance information collected by the single-chip microcomputer is transmitted to the network and displayed on pages. Workers can judge whether the power station needs to be accurately maintained through data presented on pages, so that the potential safety hazards of property resulted from decrease in classification of wind resistance for photovoltaic modules are avoided, and the problem of hidden cracks generated by vibration of the boards after the photovoltaic modules are loosened is solved.

Secondly, loosened parts of the modules can be effectively distinguished through the identification of different coding resistances after the screws are loosened. The positioning of the loosened modules is realized through forward detection. The judgment of the number of loosened screws is realized through reverse detection. Maintenance conditions are preset according to the dangerous degree of looseness of the photovoltaic modules to ensure real-time monitoring and maintain the safety of the modules.

Thirdly, a breakpoint detection method based on bi-directional detection is applicable to the field of large-scale screw detection. The problem in the prior art that loosened screws are difficult to position is solved. The device is easy to mount, and is high in adaptability with different occasions and wide in application range. The monitoring of screw loose in the whole power station can be realized for a long time, so that the economic cost is low.

### BRIEF DESCRIPTION OF THE DRAWINGS

To more clearly illustrate the present embodiment of the present disclosure or the technical scheme in the prior art, the following briefly introduces the attached figures to be used in the present embodiments. Apparently, the attached figures in the following description show merely some embodiments of the present disclosure, and those skilled in the art may still derive other drawings from these attached figures without creative efforts.

FIG. 1 is a structural schematic diagram of a photovoltaic panels in the present disclosure.

FIG. 2 is a structural schematic diagram of a support beams in the present disclosure.

FIG. 3 is a structural schematic diagram of a sensor in the present disclosure.

FIG. 4 is a structural schematic diagram of a hoop side pressure sensor device in the present disclosure.

FIG. 5 is a structural schematic diagram of a side pressure sensor device in the present disclosure.

FIG. 6 is a side view of a side pressure sensor device in the present disclosure.

FIG. 7 is a section view of a side pressure sensor device in the present disclosure.

FIG. 8 is a connection schematic diagram of sensors in the present disclosure.

FIG. 9 is a connection schematic diagram of a sensor network in the present disclosure.

FIG. 10 is a work flow diagram in the present disclosure.

Reference signs: 1, buckle belt; 10, photovoltaic panel; 11, support beam; 12, blank holder; 13, first support; 14, second support; 15, relay; 16, digital potentiometer; 17, single-chip microcomputer; 18, wireless transmission module; 19, box; 2, circular slot; 20, heat emission hole; 3, column plug; 4, sensor device; 40, top cover; 401, first plug; 402, first spring; 403, insulation joint; 411, square notch; 412, first thread line; 413, second thread line; 42, rotating circular ring; 43, bottom cover; 431, first wire outlet; 432, second wire outlet; 44, baffle plate; 441, round hole; 45, partition plate; 46, metal sheet; 461, lead wire port; 462, socket; 5, screw; 6, nut; 7, first gasket; 8, second gasket; 9, second spring; and 47, wire.

### DETAILED DESCRIPTION OF THE EMBODIMENTS

The following clearly and completely describes the technical scheme in the embodiments of the present disclosure with reference to the accompanying drawings of the embodiments of the present disclosure. Apparently, the described embodiments are merely a part rather than all of the embodiments of the present disclosure. Based on the embodiments in the present disclosure, all other embodiments acquired by those of ordinary skill staff in the art under the premise of without contributing creative labor belong to the scope protected by the present disclosure.

In the description of the present disclosure, it needs to be illustrated that the indicative directions or position relations of the terms such as “upper”, “lower”, “inner”, “outer”, “front end”, “rear end”, “both ends”, “one end” and “the other end” are directions or position relations illustrated based on the attached figures, just for facilitating the description of the present disclosure and simplifying the description, but not for indicating or hinting that the indicated devices or elements must be in a specific direction and are constructed and operated in the specific directions, the terms cannot be understood as the restriction of the present disclosure. Moreover, the terms such as “first” and “second” are just used for distinguishing the description, but cannot be understood to indicate or hint relative importance.

In the description of the present disclosure, it needs to be illustrated that, except as otherwise noted, the terms such as “install”, “provided with” and “connect” should be generally understood, for example, the components can be fixedly connected, and also can be detachably connected or integrally connected; the components can be mechanically connected, and also can be electrically connected; the components can be directly connected and also can be indirectly connected through an intermediate, and two components can be communicated internally. For those skilled in the art, the specific meanings of the terms in the present disclosure can be understood according to specific conditions.

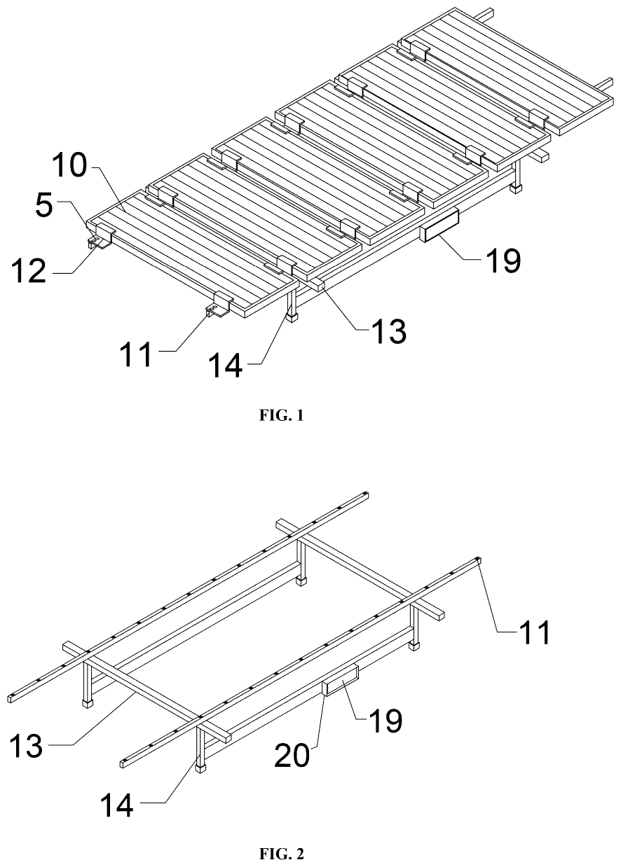

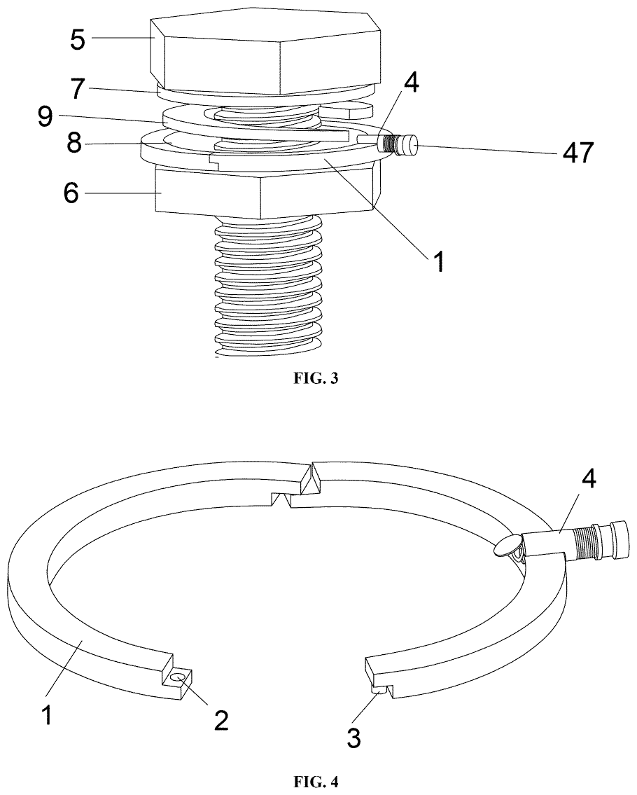

Referring to FIG. 1 and FIG. 2, according to an embodiment provided by the present disclosure, a breakpoint detection device based on bi-directional detection includes second supports 14. The tops of the second supports 14 are connected with first supports 13. The tops of the first supports 13 are symmetrically connected with support beams 11. The first supports 13 are supported by the second supports 14. The first supports 13 are used for providing mounting space for photovoltaic panels 10 through the support beams 11. Screws 5, nuts 6 and blank holders 12 are used for carrying out positioning mounting on the positions of the photovoltaic panels 10. The tops of the support beams 11 are sequentially provided with the photovoltaic panels 10 and the blank holders 12 in a staggered manner. A sensor device 4 is in a shape of a hollow column and is embedded in a buckle belt 1. A column plug 3 is cylindrical in shape. The outside dimension of the column plug 3 is equal to the inside dimension of a circular slot 2. A first gasket 7 and a second gasket 8 are disc-shaped in shape. A metal sheet 46 and a partition plate 45 are both disc-shaped. The dimensions of the metal sheet 46 and the partition plate 45 are equal to the inside dimension of the sensor device 4. A side surface of a first plug 401 is fixedly connected with a wire 47 which penetrates through a round hole 441 of a baffle plate 44 and a lead wire port 461 of the metal sheet 46 and finally is led out through a first wire outlet 431 of a bottom cover 43. One end of the metal sheet 46 is also connected with a wire 47 which is led out through a second wire outlet 432 of the bottom cover 43.

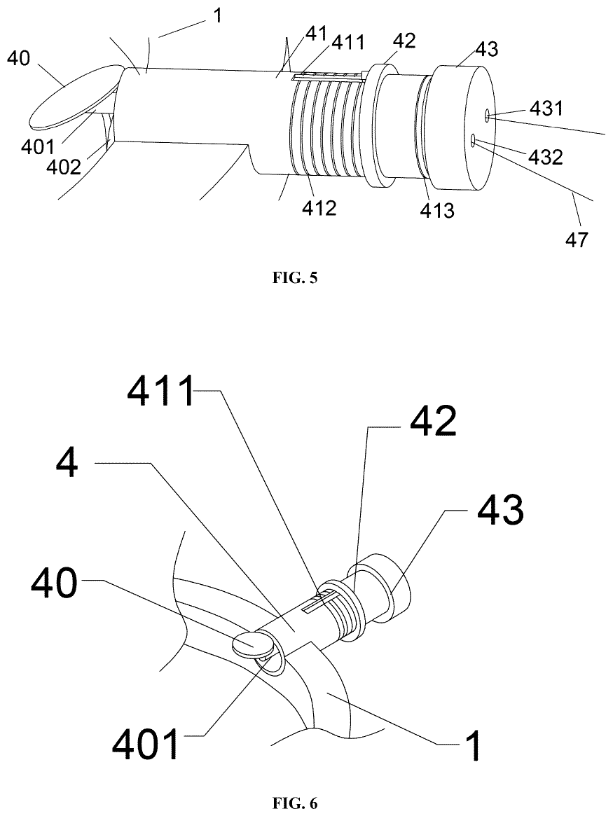

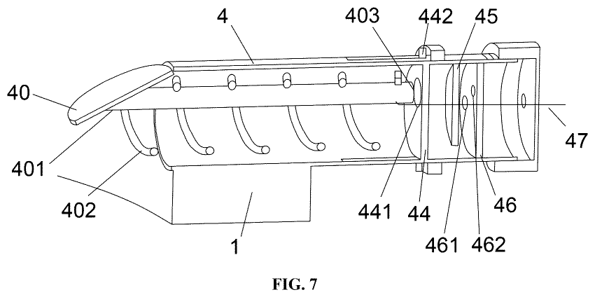

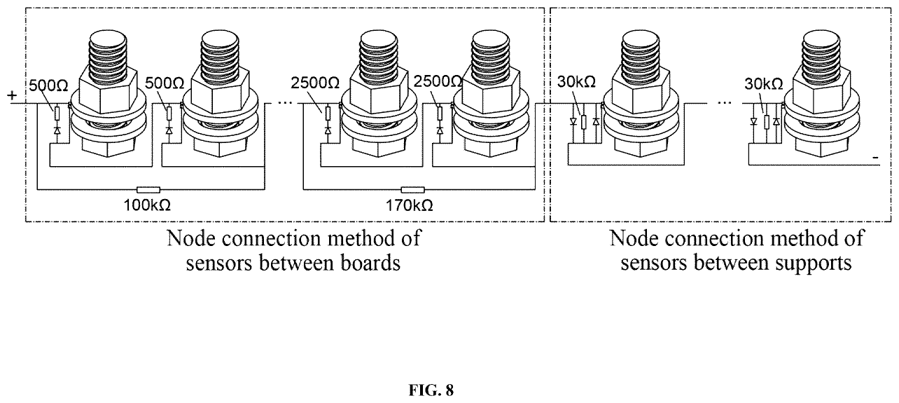

Referring to FIG. 2, FIG. 3, FIG. 4, FIG. 5, FIG. 6 and FIG. 7, the screws 5 penetrate through inner walls of the support beams 5. An outer wall of the screw 5 is provided with the buckle belt 1. An inner wall of the buckle belt 1 is provided with the sensor device 4. The sensor device 4 includes a top cover 40, the first plug 401, a first spring 402, an insulation joint 3 and the baffle plate 44. The baffle plate 44 is arranged inside the sensor device 4. One end of the first spring 402 is fixedly connected with an outer wall of the baffle plate 44. The round hole 441 is formed in an inner wall of the baffle plate 44. The first plug 401 penetrates through an inner wall of the round hole 441. One end of the first plug 401 is connected with the insulation joint 403. One end of the sensor device 4 is provided with the top cover 40. The buckle belt 1 includes the circular slot 2 and the column plug 3. The circular slot 2 is formed in the interior of the buckle belt 1. The column plug 3 penetrates through the interior of the circular slot 2. One end of the column plug 3 is fixedly connected with an outer wall of the buckle belt 1. A side surface of the first plug 401 is fixedly connected with a wire 47 which penetrates through the round hole 441 of the baffle plate 44. The wire penetrates through the lead wire port 461 of the metal sheet 46 at the same time, and finally is led out through the first wire outlet 431 of the bottom cover 43. One end of the metal sheet 46 is also connected with a wire 47 which is led out through the second wire outlet 432 of the bottom cover 43. The function of the two wires 47 is that when the insulation joint 403 of the first plug 401 is completely inserted into a socket 462 of the metal sheet 46, a front end surface of the first plug 401 is in contact with the metal sheet 46 to form a conducting loop. An outer wall of the second support 14 is provided with a box 19. The box 19 includes a relay 15, a digital potentiometer 16, a single-chip microcomputer 17 and a wireless transmission module 18. The relay 15, the digital potentiometer 16, the single-chip microcomputer 17 and the wireless transmission module 18 are all arranged inside the box 19 and electrically connected. A heat emission hole 20 is formed in an outer wall of the box 19. The sensor is composed of the screw 5, the nut 6, the sensor device 4, the buckle belt 1, spring and gaskets. The screws 5 fixed on board on one photovoltaic module are mainly distributed at four corners. The photovoltaic panel 10 and the support beam 11 are connected through the blank holder 12 at each corner. All screws 5 at the same corner are taken as a sensor. Four sensors are shared on the same photovoltaic panel 10. At least one edge between the adjacent photovoltaic modules is adjacent. Two blank holders 12 are shared on the adjacent edge so that upper and lower corners are fixed. Two sensors are shared on each adjacent edge. Eighteen sensors are needed for the screws 5 fixed on boards of eight photovoltaic panels 10. There are mainly two parts for the screws 5 fixed between the supports. One part of screws 5 are screws for fixing the first supports and the support beams, and there are two first supports. There are four fixed points between the two first supports 13 and the support beams, so four sensor nodes are needed. The other part of screws 5 are screws for fixing the second supports to the ground, and there are four second supports. There are four fixed points between the four second supports and the ground, and there are four sensors, so there are eight sensors fixed between the supports of the photovoltaic panels 10. In order to distinguish the detections of loosened screws at different parts, as shown in FIG. 8, both ends of every two sensors are connected with a wire with the resistance value of (=100Ω, 110Ω, 120Ω, . . . , 160Ω, 170Ω, wherein i is equal to 1, 2, 3, . . . , 7, 8) in parallel as features for detecting the screws 5 fixed on boards. In the first step, the wires of the sensor are respectively connected with two diodes and a resistance with the resistance value of 30 kΩ in parallel as a feature for detecting the screws fixed between the supports. The column plug 3 is fixedly connected to the position the buckle belt 1 by the circular slot 2. The looseness of the board is detected with Rᵢ (100K-170K, wherein i is equal to 1, 2, . . . , 8). The phenomenon that screws are loosened on which edge specifically in this string of photovoltaic modules can be judged through the corresponding resistance value, and then the number of loosened screws on the edge can be judged in the subsequent reverse detection. Two sensors are serially connected, and then are connected with a resistance Rᵢ in parallel. The looseness of the supports are detected with a. Each resistance value is 30 kΩ. The number of loosened supports can be judged through the difference of two equivalent resistances/30 kΩ obtained through the voltage at both ends. During the reverse detection, the number of loosened boards is detected with rᵢ, and the resistance values are 500, 1000, 1500, 2000 and 2500.

Referring to FIG. 3, the nut 6 is mounted around the outer wall of the screw 5, and the nut 6 is located below the buckle belt 1. The outer wall of the screw 5 is symmetrically provided with the first gasket 7 and the second gasket 8, and the outer wall of the buckle belt 1 is connected with an outer wall of the second gasket 8. A second spring 9 is arranged between the first gasket 7 and the second gasket 8. The second spring 9 can push the first gasket 7 and the second gasket 8 to be separated in position after the screw 5 and the nut 6 are loosened. When the screw 5 is tightened, the first gasket 7 and the second spring 9 on the second gasket 8 are mutually extruded, and the second spring 9 on the second gasket 8 is deformed, so that the sensor is in a low-resistance state. When the screw 5 is loosened, the first gasket 7 and the second gasket 8 are restored, so that the sensor is in a high-resistance state.

Referring to FIG. 5 and FIG. 7, a square notch 411 is formed in an outer wall of the sensor device 4. The outer wall of the sensor device 4 is provided with a first thread line 412, and the first thread line 412 is located on two sides of the square notch 411. The outer wall of the sensor device 4 is provided with a second thread line 413, and the second thread line 413 is located on one side of the first thread line 412. An outer wall of the second thread line 413 is provided with the bottom cover 413. The first wire outlet 431 and the second wire outlet 432 are symmetrically formed in an outer wall of the bottom cover 43. An inner wall of the sensor device 4 is provided with the metal sheet 46, and the metal sheet 46 is located on one side of the baffle plate 44. The lead wire port 461 is formed in an outer wall of the metal sheet 46. The socket 462 is formed in the outer wall of the metal sheet 46, and one end of the insulation joint 403 extends to the interior of the socket 462. The inner wall of the sensor device 4 is provided with the partition plate 45. An outer wall of the first thread line 412 is provided with a rotating circular ring 42. The first thread line 412 is convenient for the rotation of the rotating circular ring 42, and the second thread line 413 is used for connecting the bottom cover 43 with the sensor device 4. The external pin ports are respectively connected with two wires as positive and negative electrodes of the sensor, and extend to the interior of the sensor device 4 through the first wire outlet 431 and the second wire outlet 432 for connection.

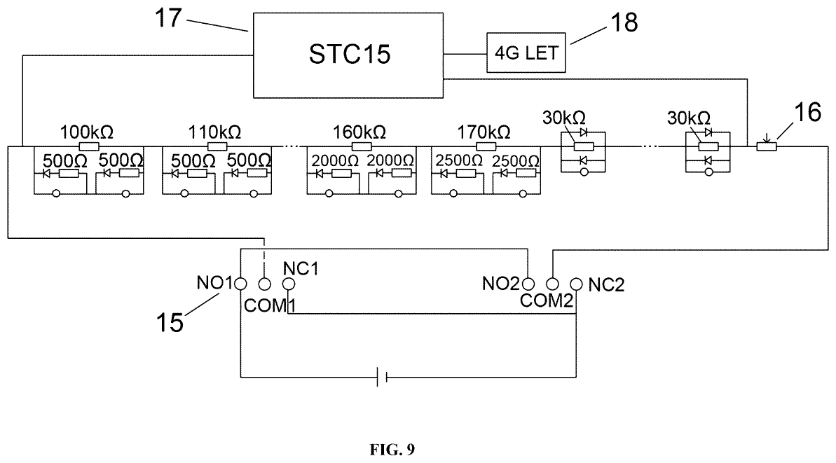

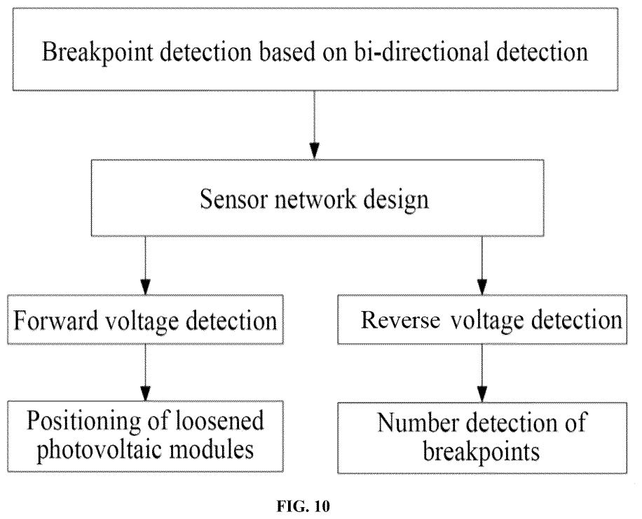

Referring to FIG. 8 and FIG. 9, a use method of the breakpoint detection device based on bi-directional detection. A breakpoint detection implementation method based on bi-directional detection includes the following steps: a first step, sensor network design, including sensor design, detection design of loosened screws 5 of photovoltaic modules at different positions, and sensor network connection design; a second step, forward voltage detection to position loosened photovoltaic modules; a third step, reverse voltage detection to judge the number of breakpoints of loosened photovoltaic modules; a fourth step, traversal algorithm design.

the sensor in the first step is composed of the screw 5, the nut 6, gaskets, the spring and a hoop side pressure sensor device. The first gasket 7, the second spring 9 and the second gasket 8 are placed on the screw 5 in sequence. The nut is tightened along the thread line. A surface of the second spring 9 is completely pressed into a plane. The second gasket 8 is wrapped with the buckle belt 1 of a hoop side pressure device, and the circular slot 2 is tightly buckled with the column plug 3. At this time, the top cover 40 of the side pressure sensor device directly faces the first gasket 7 and is extruded outwards by the first gasket 7. The displacement of the top cover 40 drives the connected first plug 401 and first spring 402 to push inwards, so that the first plug 401 penetrates through the round hole 441 inside the baffle plate 44. When the side pressure sensor device is completely covered with the top cover 40, the insulation joint 403 at the rightmost end of the first plug 401 is completely inserted into the socket 462 of the metal sheet 46. At this time, a front end surface of the first plug 401 is completely laminated to the metal sheet 46 to form a conducting loop, so that the sensor is in a low-resistance state. When the screw is loosened, the second spring 9 is restored. The first gasket 7 and the second gasket 8 are bounced off by force. The top cover 40 of the side pressure sensor device is not extruded by the second spring 9 any more. The first spring 402 connected with the top cover 40 is restored to push the top cover 40 to displace towards the direction of the screw. The displacement of the top cover 40 drives the first plug 401 to displace towards the direction of the screw at the same time. The insulation joint 403 on the top of the first plug 401 drives the metal sheet 46 to move for a certain distance and is blocked and separated by the partition plate 45. At this time, the front end surface of the first plug 401 is not in contact with the metal sheet 46 any more, and the conducting loop becomes a disconnected loop, so that the sensor is in a high-resistance state.

For the side pressure sensor device in the first step, when the screw is loosened, the insulation joint 403 on the top of the first plug 401 drives the metal sheet 46 to move for a certain distance, so that a certain travel is provided for detecting a tightened state to a loosened state for the sensor. The baffle plate 44 can be controlled to move forward (reverse) by the rotating circular ring 42, so that the baffle plate 44 drives the first spring 402 to move forward (reverse) so as to achieve the purpose of controlling the protrusion angle of the top cover 40. The distance between the metal sheet 46 and the bottom cover 43 is controlled by rotating the bottom cover 43 so as to ensure that the insulation joint 403 of the first plug 401 can be completely pushed into the socket 462 of the metal sheet 46 when the top cover 40 is completely extruded by the first spring 402.

For the detection design of loosened screws of photovoltaic modules at different positions in the first step, the screws of the distributed photovoltaic power station are distributed in two types of positions, including screws fixed on boards and screws fixed between supports. The screws fixed on board on one photovoltaic module are mainly distributed at four corners. All screws at the same corner are taken as one sensor, and four sensors are shared on the same photovoltaic module. When at least one edge is adjacent between the adjacent photovoltaic modules, two screws are shared on the adjacent edge to fix upper and lower corners, two sensors are shared on each adjacent edge, and 2N+2 sensors are needed for the screws fixed on boards on N photovoltaic modules. When the screws fixed between the supports on N photovoltaic modules are divided into M groups, the screws fixed at the same corner of each support are taken as one sensor.

For a feature recognition method of loosened screws of photovoltaic modules at different positions, in the first step, the wires at both ends of the sensor are connected with a wire with the diode string resistance value of rᵢ as a feature for detecting the number of the screws loosened on boards. Every n sensors are serially connected together, and a coding resistance with the resistance value of Rᵢ is connected at both ends in parallel as a feature for detecting screws loosened on boards. In the first step, the wires of the sensor is respectively connected with two diodes and a resistance with the resistance value of a in parallel as a feature for detecting the screws fixed between the supports.

For the sensor network connection design in the first step, a negative electrode in each sensor in the photovoltaic modules is connected with a positive electrode of the next sensor through a wire, every n sensors are serially connected together, a coding resistance with the resistance value of Rᵢ is connected at both ends in parallel, as a sensor branch, a wire is led out at the negative electrode of each sensor branch to be connected with the positive electrode of the next sensor branch, and all sensor branches are serially connected to form a sensor network.

For the forward voltage detection in the second step, two forward voltages are applied to N photovoltaic modules by a power source. When all screws on the N photovoltaic modules are tightened, the sensor network is in a low-resistance state, all coding resistances Rᵢ are all short-circuited, and the overall resistance value of the N photovoltaic modules measured by the two forward voltages is just the internal resistance of the wires. When the equivalent resistance values measured by the two voltages are the same, but extremely larger than the internal resistance of the wires, it is indicated that breakpoints appear at the joint of the board of the photovoltaic modules (the screws are loosened). The corresponding sensors are in a high-resistance state, and the detected equivalent resistance of N photovoltaic modules is the sum of the corresponding coding resistances Rᵢ and the internal resistance of the wires. When the equivalent resistance values measured by the two voltages are different, it is indicated that breakpoints appear at the joints of the supports of the photovoltaic modules, the corresponding sensors are in a high-resistance state, and the difference between the two detected equivalent resistances of N photovoltaic modules is the sum of the corresponding coding resistances ai and the internal resistance of the wires.

Through the forward voltage detection in the second step, precision positioning for the loosened photovoltaic modules can be realized. According to the contrast between the equivalent resistance and the coding resistances Rᵢ or ai, breakpoints at the joints of the boards or at the joints of the supports can be distinguished.

For the reverse voltage detection in the third step, when breakpoints appear at the joints of the boards of the photovoltaic modules in the third step, two different reverse voltages are applied to the N photovoltaic modules to measure two current values, and the resistance values is obtained through the formula

$$r = \frac{Δ U}{Δ I}$$

to be contrasted with the coding resistances rᵢ so as to judge the number of the breakpoints of the loosened photovoltaic modules.

Power switching between the forward voltage and the reverse voltage in the second step and the third step is realized by controlling two relays by the single-chip microcomputer.

For the supply of the two different voltages in the second step and the third step, the digital potentiometer and the sensor network formed by the N photovoltaic modules are serially connected. Voltages are applied forward and reverse for the whole circuit by the power source, and different partial voltages for the sensors can be realized by changing the programmable resistance value in the digital potentiometer.

For the traversal algorithm design in the fourth step, the superposition of various different coding resistances may result in the same resistance result respectively detected by the forward voltage in the second step and the reverse voltage in the third step, thus various possible reasons corresponding to the same resistance result detected by the forward voltage and various possible reasons corresponding to the same resistance result detected by reverse voltage respectively need to be recognized through the traversal algorithm, and an intersection of the possible reasons is taken to achieve the purposes of positioning the loosened photovoltaic modules and detecting the number of breakpoints. During detection, the sum of the values of R1, R2 and R5 in the forward detection process is just equal to the sum of the values of R2, R3 and R4. When such condition appears, forward detection cannot identify which group of photovoltaic panels is loosened specifically. Therefore, through traversal algorithm, the measured equivalent resistance can be effectively identified to be resulted from such two combinations possibly. And then, through reverse detection, a resistance value is obtained. The resistance value may also be of several possibilities, and then the phenomenon that which group of photovoltaic panels is loosened can be judged specifically by taking the intersection of forward and reverse detection. The resistance value measured by reverse detection is just equal to the sum of r1, r2 and r5 (the first, the second and the fifth board edges are loosened), and is also equal to the sum of r1, r3 and r4 (the first, the third and the fourth board edges are loosened). In combination with the previous forward detection, it can be judged that the looseness is resulted from the looseness of the first, the second and the fifth board edges, and then the phenomenon that which group of photovoltaic panels is loosened specifically is determined. One resistance value result may correspond to various possibilities through forward detection, thus those various possibilities corresponding to all different results can be found through code presetting. Therefore, the obtained resistance value result may be of concentrated possibility in all preset possibility results, or reverse vice versa. Which photovoltaic modules are loosened and the number of loosened screws can be judged by taking two possibility intersections through forward and reverse detection.

A fifth step, maintenance condition judgment; the maintenance conditions are as follows: (1) when breakpoints exist on two of the four corners of a certain photovoltaic module, the loosened photovoltaic module needs to be maintained; (2) when one breakpoint exists on all unadjacent photovoltaic modules, all photovoltaic modules with breakpoint need to be maintained.

The photovoltaic modules are divided into M groups, and every N photovoltaic modules form one group; M pin ports are respectively connected with M groups of circuits through the single-chip microcomputer, and the M groups of circuits are arranged in the shape of a star; the single-chip microcomputer is placed in the center of the star; the transmission rate of signals is increased; and the state information of all screws on the M×N photovoltaic modules can be collected by one single-chip microcomputer, so that the production cost is reduced.

The sensor network connection design in the first step is as follows. The negative electrode in each sensor in the photovoltaic modules is connected with the positive electrode of the next sensor through a wire, so that all sensors on one photovoltaic module are serially connected together. For the detection of screws loosened on boards, a coding resistance with the resistance value of (=100 kΩ, 110 kΩ, 120 kΩ, . . . 170 kΩ, wherein i is equal to 1, 2, . . . , 8) is connected in parallel at both ends of every 2 sensors. In addition to connecting the negative electrode of the sensor on the last screw of each photovoltaic module with the corresponding coding resistance, a wire is also led to connect with the positive electrode of the first sensor of the next photovoltaic module.

In forward voltage detection step, two forward voltages are applied to eight photovoltaic modules through the power source. When all screws on the eight photovoltaic modules are tightened, the sensor network is in a low-resistance state, all coding resistances are all short-circuited, and the overall resistance value of the eight photovoltaic modules measured by the two forward voltages is just the internal resistance of the wires. When the equivalent resistance values measured by the two voltages are the same, but extremely larger than the internal resistance of the wires, it is indicated that breakpoints appear at the joints of the boards of the photovoltaic modules (the screws are loosened). The corresponding sensors are in a high-resistance state, and the detected equivalent resistance of eight photovoltaic modules is the sum of the corresponding coding resistances and the internal resistance of the wires. When the equivalent resistance values measured by the two voltages are different, it is indicated that breakpoints appear at the joints of the supports of the photovoltaic modules (the screws are loosened), the corresponding sensors are in a high-resistance state, and the difference between the two detected equivalent resistances of N photovoltaic modules is the sum of a multiple relation value of the corresponding coding resistance 30kΩ and the internal resistance of the wires.

Further, through the forward voltage detection in the second step, precision positioning for the loosened photovoltaic modules can be realized. According to the contrast between the two equivalent resistances, breakpoints at the joints of the boards or at the joints of the supports can be distinguished.

Further, for the reverse voltage detection in the third step, when breakpoints appear at the joints of the boards of the photovoltaic modules in the second step, two different reverse voltages are applied to the N photovoltaic modules to measure two current values, and the number of the breakpoints of the loosened photovoltaic modules is judged through the contrast between the resistance value in the formula and the coding resistances.

Further, different reverse voltages are provided in the third step, and the digital potentiometer and the sensor network formed by the N photovoltaic modules are connected in series. Voltages are applied reverse for the whole circuit by the power source, and different partial voltages for the sensors can be realized by changing the programmable resistance value in the digital potentiometer.

Further, the superposition of various different coding resistances may result in the same resistance result respectively detected by the forward voltages in the second step and the reverse voltages in the third step, thus various possible reasons corresponding to the same resistance result detected by the forward voltages and various possible reasons corresponding to the same resistance result detected by reverse voltages respectively need to be recognized through traversal algorithm in the fourth step, and the intersection of the possible reasons is taken to achieve the purposes of positioning the loosened photovoltaic modules and detecting the number of breakpoints. The sum of the values of R1, R2 and R5 in the forward detection process is just equal to the sum of the values of R2, R3 and R4. When such condition appears, reverse detection cannot identify which group of photovoltaic panels is loosened specifically. Therefore, through traversal algorithm, the measured equivalent resistance can be effectively identified to be resulted from such two combinations possibly. And then, through reverse detection, a resistance value is obtained. The resistance value may also be of several possibilities, and then the phenomenon that which group of photovoltaic panels is loosened can be judged specifically by taking the intersection of forward and reverse detection. The resistance value measured by reverse detection is just equal to the sum of r1, r2 and r5 (the first, the second and the fifth board edges are loosened), and is also equal to the sum of r1, r3 and r4 (the first, the third and the fourth board edges are loosened). In combination with the previous forward detection, it can be judged that the looseness is resulted from the looseness of the first, the second and the fifth board edges, and then the phenomenon that which group of photovoltaic panels is loosened specifically is determined.

Power switching between the forward voltages and the reverse voltages in the second step and the third step is realized by controlling two relays by the single-chip microcomputer. When forward voltages are determined to be given, a normally opened port NO1 of the first relay is connected with a common port COM1, and a normally closed port NC2 of the second relay is connected with a common port COM2, thus a closed loop is formed to realized forward power supply. When forward voltages are determined to be given, a normally closed port NC1 of the first relay is connected with a common port COM1, and a normally closed port NO2 of the second relay is connected with the common port COM2, thus a closed loop is formed to realized reverse power supply.

A fifth step, is maintenance condition judgment. The maintenance conditions are as follows: (1) when breakpoints exist on two of the four corners of a certain photovoltaic module, the loosened photovoltaic module needs to be maintained. (2) when one breakpoint exists on all unadjacent photovoltaic modules, all photovoltaic modules with breakpoint need to be maintained.

Further, the photovoltaic modules are divided into sixteen groups, and every eight photovoltaic modules form one group; sixteen pin ports are respectively connected with sixteen groups of circuits through the single-chip microcomputer, and the sixteen groups of circuits are arranged in the shape of a star. The single-chip microcomputer is placed in the center of the star. The transmission rate of signals is increased. The state information of all screws on the 144 photovoltaic modules can be collected by one single-chip microcomputer, so that the production cost is greatly reduced.

According to the working principle, firstly, the sensor is composed of the screw, the nut, gaskets, the spring and a hoop side pressure sensor. The screws 5 fixed on board on one photovoltaic module are mainly distributed at four corners. The photovoltaic panel 10 is connected with the support beam 11 through the blank holder 12 at each corner. All screws 5 at the same corner are taken as one sensor, and four sensors are shared on the same photovoltaic panel 10. When at least one edge is adjacent between the adjacent photovoltaic modules, two blank holders 12 are shared on the adjacent edge to fix upper and lower corners, two sensors are shared on each adjacent edge, and eighteen sensors are needed for the screws 5 fixed on boards on eight photovoltaic panels 10. There are mainly two parts for the screws 5 fixed between the supports. One part of screws 5 are screws for fixing the first supports and the support beams, and there are two first supports. There are four fixed points between the two first supports 13 and the support beams, so four sensor nodes are needed. The other part of screws 5 are screws for fixing the second supports to the ground, and there are four second supports. There are four fixed points between the four second supports and the ground, and there are four sensors, so there are eight sensors fixed between the supports of the photovoltaic panels 10. In order to distinguish the detection of loosened screws at different parts, as shown in FIG. 8, both ends of every two sensors are connected with a wire, provided with a resistance, with the resistance value of (=100KΩ, 110KΩ, 120Ω, . . . , 160 Ω, 170KΩ, wherein i is equal to 1, 2, 3, . . . , 7, 8) in parallel as a feature for detecting the screws 5 fixed on boards. In the first step, the wire of the sensor is respectively connected with two diodes and a resistance with the resistance value of 30 kΩ in parallel as a feature for detecting the screws 5 fixed between the supports. The column plug 3 is fixedly connected the position of the buckle belt 1 through the circular slot 2. When the screw is loosened, the insulation joint 403 on the top of the first plug 401 drives the metal sheet 46 to move for a certain distance, so that a certain travel is provided for detecting a tightened state to a loosened state by the sensor. The baffle plate 44 can be controlled to move forward (reverse) by the rotating circular ring 42, so that the baffle plate 44 drives the first spring 402 to move forward (reverse) so as to achieve the purpose of controlling the protrusion angle of the top cover 40. The distance between the metal sheet 46 and the bottom cover 43 is controlled by rotating the bottom cover 43 so as to ensure that the insulation joint 403 of the first plug 401 can be completely pushed into the socket 462 of the metal sheet 46 when the top cover 40 is completely extruded by the first spring 402. When the insulation joint 403 of the first plug 401 is completely inserted into the socket 462 of the metal sheet 46, a front end surface of the first plug 401 is in contact with the metal sheet 46 to form a conducting loop.

For those skilled in the art, obviously the present disclosure is not limited to the details of the above exemplary embodiments, and the present disclosure can be achieved in other specific forms without departing from the spirit or essential characteristics of the present disclosure. Therefore, for every point, the embodiments should be regarded as exemplary embodiments and are unrestrictive, the scope of the present disclosure is restricted by the claims appended hereto not above exemplary limits, and therefore, all changes, including the meanings and scopes of equivalent elements, of the claims are aimed to be included in the present disclosure. Any mark of attached figures in the claims should not be regarded as limitation to the involved claims.

Specific examples are used for illustration of the principles and implementation methods of the present disclosure. The description of the above-mentioned embodiments is used to help illustrate the method and its core principles of the present disclosure. In addition, those skilled in the art can make various modifications in terms of specific embodiments and scope of application in accordance with the teachings of the present disclosure. In summary, the contents of this specification should not be understood as the limitation of the present disclosure.

1. A breakpoint detection device based on bi-directional detection, comprising:
second supports (14), wherein tops of the second supports (14) are connected with first supports (13), tops of the first supports (13) are symmetrically connected with support beams (11), and tops of the support beams (11) are sequentially provided with photovoltaic panels (10) and blank holders (12) in a staggered manner;
wherein screws (5) penetrate through inner walls of the support beams (11), an outer wall of each screw (5) is provided with a buckle belt (1), and an inner wall of the buckle belt (1) is provided with a sensor device (4);
wherein the sensor device (4) comprises a top cover (40), a first plug (401), a first spring (402), an insulation joint (403) and a baffle plate (44), the baffle plate (44) is arranged inside the sensor device (4), one end of the first spring (402) is fixedly connected with an outer wall of the baffle plate (44), a round hole (441) is formed in an inner wall of the baffle plate (44), the first plug (401) penetrates through an inner wall of the round hole (441), one end of the first plug (401) is connected with the insulation joint (403), and one end of the sensor device (4) is provided with the top cover (40).

2. The breakpoint detection device based on bi-directional detection according to claim 1, wherein the buckle belt (1) comprises a circular slot (2) and a column plug (3), the circular slot (2) is formed in an interior of the buckle belt (1), the column plug (3) penetrates through an interior of the circular slot (2), and one end of the column plug (3) is fixedly connected with an outer wall of the buckle belt (1).

3. The breakpoint detection device based on bi-directional detection according to claim 2, wherein a nut (6) is mounted around the outer wall of the screw (5), the nut (6) is located below the buckle belt (1), the outer wall of the screw (5) is symmetrically provided with a first gasket (7) and a second gasket (8), the outer wall of the buckle belt (1) is connected with an outer wall of the second gasket (8), and a second spring (9) is arranged between the first gasket (7) and the second gasket (8).

4. The breakpoint detection device based on bi-directional detection according to claim 3, wherein a square notch (411) is formed in an outer wall of the sensor device (4), the outer wall of the sensor device (4) is provided with a first thread line (412), the first thread line (412) is located on one side of the square notch (411), the outer wall of the sensor device (4) is provided with a second thread line (413), the second thread line (413) is located on one side of the first thread line (412), an outer wall of the second thread line (413) is provided with a bottom cover (413), a first wire outlet (431) and a second wire outlet (432) are symmetrically formed in an outer wall of the bottom cover (43), an inner wall of the sensor device (4) is provided with a metal sheet (46), the metal sheet (46) is located on one side of the baffle plate (44), a lead wire port (461) is formed in an outer wall of the metal sheet (46), a socket (462) is formed in the outer wall of the metal sheet (46), one end of the insulation joint (43) extends to the interior of the socket (462), the inner wall of the sensor device (4) is provided with a partition plate (45), and an outer wall of the first thread line (412) is provided with a rotating circular ring (42).

5. The breakpoint detection device based on bi-directional detection according to claim 4, wherein the sensor device (4) is in a shape of a hollow column and is embedded in the buckle belt (1), the column plug (3) is cylindrical in shape, an outside dimension of the column plug (3) is equal to an inside dimension of the circular slot (2), the first gasket (7) and the second gasket (8) are disc-shaped in shape, the metal sheet (46) and the partition plate (45) are both disc-shaped, dimensions of the metal sheet (46) and the partition plate (45) are equal to an inside dimension of the sensor device (4), a side surface of the first plug (401) is fixedly connected with a wire (47) which penetrates through the round hole (441) of the baffle plate (44) and the lead wire port (461) of the metal sheet (46) and finally is led out through the first wire outlet (431) of the bottom cover (43), one end of the metal sheet (46) is also connected with a wire (47) which is led out through the second wire outlet (432) of the bottom cover (43).

6. The breakpoint detection device based on bi-directional detection according to claim 1, wherein an outer wall of each second support (14) is provided with a box (19), the box (19) comprises a relay (15), a digital potentiometer (16), a single-chip microcomputer (17) and a wireless transmission module (18), the relay (15), the digital potentiometer (16), the single-chip microcomputer (17) and the wireless transmission module (18) are all arranged inside the box (19) and electrically connected, and a heat emission hole (20) is formed in an outer wall of the box (19).

7. A use method of the breakpoint detection device based on bi-directional detection, applicable to the breakpoint detection device based on bi-directional detection according to claim 1, wherein an implementation method of the breakpoint detection device based on bi-directional detection comprises following steps:
a first step 1: sensor network design, comprising sensor design, detection design of loosened screws of photovoltaic modules at different positions, and sensor network connection design;
a second step: forward voltage detection to position loosened photovoltaic modules;
a third step, reverse voltage detection to judge a number of breakpoints of the loosened photovoltaic modules;
a fourth step, traversal algorithm design;
wherein a sensor in the first step is composed of the screw, the nut, gaskets, a spring and a hoop side pressure sensor; the first gasket, the second spring and the second gasket are placed on the screw in sequence; the nut is tightened along a thread line; a surface of the second spring is completely pressed into a plane; the second gasket is wrapped with the buckle belt of a hoop side pressure device, and the circular slot is tightly buckled with the column plug; at this time, the top cover of the sensor device directly faces the first gasket and is extruded outwards by the first gasket; an displacement of the top cover drives the connected first plug and first spring to push inwards, so that the first plug penetrates through the round hole inside the baffle plate; when the sensor device is completely covered with the top cover, the insulation joint at a rightmost end of the first plug is completely inserted into the socket of the metal sheet; at this time, a front end surface of the first plug is completely laminated to the metal sheet to form a conducting loop, so that the sensor is in a low-resistance state; when the screw is loosened, the second spring is restored, the first gasket and the second gasket are bounced off by force, the top cover of the sensor device is not extruded by the second spring any more, the first spring connected with the top cover is restored to push the top cover to displace towards a direction of the screw, a displacement of the top cover drives the first plug to displace towards the direction of the screw at a same time, the insulation joint on a top of the first plug drives the metal sheet to move for a certain distance and is blocked and separated by the partition plate, at this time, the front end surface of the first plug is not in contact with the metal sheet any more, and the conducting loop becomes a disconnected loop, so that the sensor is in a high-resistance state;
for a loop side pressure device in the first step, when the screw is loosened, the insulation joint on the top of the first plug drives the metal sheet to move for the certain distance, so that a certain travel is provided for detecting a tightened state to a loosened state by the sensor; the baffle plate can be controlled to move forward or reverse by the rotating circular ring, so that the baffle plate drives the first spring to move forward or reverse so as to achieve a purpose of controlling a protrusion angle of the top cover; a distance between the metal sheet and the bottom cover is controlled by rotating the bottom cover so as to ensure that the insulation joint of the first plug can be completely pushed into the socket of the metal sheet when the top cover is completely extruded by the first spring;
for the detection design of loosened screws of photovoltaic modules at different positions in the first step, the screws of a distributed photovoltaic power station are distributed in two types of positions, comprising screws fixed on boards and screws fixed between supports; the screws fixed on board on one photovoltaic module are mainly distributed at four corners, all screws at a same corner are taken as one sensor, and four sensors are shared on a same photovoltaic module; when at least one edge is adjacent between adjacent photovoltaic modules, two screws are shared on an adjacent edge to fix upper and lower corners, two sensors are shared on each adjacent edge, and 2N+2 sensors are needed for the screws fixed on boards on N photovoltaic modules; when the screws fixed between supports on the N photovoltaic modules are divided into M groups, the screws fixed at a same corner of each support are taken as one sensor;
for a feature recognition method of loosened screws of photovoltaic modules at different positions, every n sensors are serially connected together, and a coding resistance with a resistance value of Rᵢ is connected at both ends in parallel as a feature for detecting screws loosened on boards; in the first step, wires at both ends of the sensor are connected with a wire with a diode string resistance value of rᵢ as a feature for detecting a number of the screws fixed on boards; in the first step, the wires of the sensor are respectively connected with two diodes and a resistance with a resistance value of a in parallel as a feature for detecting the screws fixed between the supports; for the sensor network connection design in the first step, a negative electrode in each sensor in the photovoltaic modules is connected with a positive electrode of a next sensor through a wire, every n sensors are serially connected together, the coding resistance with the resistance value of Rᵢ is connected at both ends in parallel, as a sensor branch, a wire is led out at a negative electrode of each sensor branch to be connected with a positive electrode of a next sensor branch, and all sensor branches are serially connected to form a sensor network;
for the forward voltage detection in the second step, two forward voltages are applied to the N photovoltaic modules by a power source; when all screws on the N photovoltaic modules are tightened, the sensor network is in a low-resistance state, all coding resistances Rᵢ are all short-circuited, and an overall resistance value of the N photovoltaic modules measured by the two forward voltages is just an internal resistance of wires; when equivalent resistance values measured by the two forward voltages are same, but extremely larger than the internal resistance of the wires, it is indicated that breakpoints appear at joints of the boards of the photovoltaic modules, that is, the screws are loosened, corresponding sensors are in the high-resistance state, and a detected equivalent resistance of the N photovoltaic modules is a sum of the corresponding coding resistances Rᵢ and the internal resistance of the wires; when the equivalent resistance values measured by the two forward voltages are different, it is indicated that breakpoints appear at joints of the supports of the photovoltaic modules, corresponding sensors are in the high-resistance state, and a difference between two detected equivalent resistances of the N photovoltaic modules is a sum of the corresponding coding resistances ai and the internal resistance of the wires;
through the forward voltage detection in the second step, precision positioning for the loosened photovoltaic modules can be realized, and according to a contrast between the equivalent resistance and the coding resistances Rᵢ or ai, breakpoints at the joints of the boards or at the joints of the supports can be distinguished;
for the reverse voltage detection in the third step, when breakpoints appear at the joints of the boards of the photovoltaic modules in the third step, two different reverse voltages are applied to the N photovoltaic modules to measure two current values, and a resistance value is obtained through a formula
$$r = \frac{Δ U}{Δ I} .$$
to be contrasted with the coding resistances rᵢ so as to judge a number of the breakpoints of the loosened photovoltaic modules;
power switching between forward voltages and reverse voltages in the second step and the third step is realized by controlling two relays by the single-chip microcomputer;
for supplies of two different voltages in the second step and the third step, the digital potentiometer and the sensor network formed by the N photovoltaic modules are serially connected, voltages are applied forward and reverse for a whole circuit by the power source, and different partial voltages for the sensors can be realized by changing a programmable resistance value in the digital potentiometer;
for the traversal algorithm design in the fourth step, a superposition of various different coding resistances may result in a same resistance result respectively detected by the forward voltages in the second step and the reverse voltages in the third step, thus various possible reasons corresponding to the same resistance result detected by the forward voltages and various possible reasons corresponding to the same resistance result detected by reverse voltages respectively need to be recognized through traversal algorithm, and an intersection of possible reasons is taken to achieve a purposes of positioning the loosened photovoltaic modules and detecting the number of the breakpoints; and
a fifth step: maintenance condition judgment; wherein, maintenance conditions are as follows: (1) when breakpoints exist on two of the four corners of a certain photovoltaic module, the loosened photovoltaic module needs to be maintained; and (2) when one breakpoint exists on all unadjacent photovoltaic modules, all photovoltaic modules with the breakpoint need to be maintained;
wherein, the photovoltaic modules are divided into M groups, and every N photovoltaic modules form one group; M pin ports of the single-chip microcomputer are respectively connected with M groups of circuits, and the M groups of circuits are arranged in a shape of a star; the single-chip microcomputer is placed in a center of the star; a transmission rate of signals is increased; and a state information of all screws on M×N photovoltaic modules can be collected by one single-chip microcomputer, so that a production cost is reduced.

8. The use method of the breakpoint detection device based on bi-directional detection according to claim 7, wherein the buckle belt (1) comprises a circular slot (2) and a column plug (3), the circular slot (2) is formed in an interior of the buckle belt (1), the column plug (3) penetrates through an interior of the circular slot (2), and one end of the column plug (3) is fixedly connected with an outer wall of the buckle belt (1).

9. The use method of the breakpoint detection device based on bi-directional detection according to claim 8, wherein a nut (6) is mounted around the outer wall of the screw (5), the nut (6) is located below the buckle belt (1), the outer wall of the screw (5) is symmetrically provided with a first gasket (7) and a second gasket (8), the outer wall of the buckle belt (1) is connected with an outer wall of the second gasket (8), and a second spring (9) is arranged between the first gasket (7) and the second gasket (8).

10. The use method of the breakpoint detection device based on bi-directional detection according to claim 9, wherein a square notch (411) is formed in an outer wall of the sensor device (4), the outer wall of the sensor device (4) is provided with a first thread line (412), the first thread line (412) is located on one side of the square notch (411), the outer wall of the sensor device (4) is provided with a second thread line (413), the second thread line (413) is located on one side of the first thread line (412), an outer wall of the second thread line (413) is provided with a bottom cover (413), a first wire outlet (431) and a second wire outlet (432) are symmetrically formed in an outer wall of the bottom cover (43), an inner wall of the sensor device (4) is provided with a metal sheet (46), the metal sheet (46) is located on one side of the baffle plate (44), a lead wire port (461) is formed in an outer wall of the metal sheet (46), a socket (462) is formed in the outer wall of the metal sheet (46), one end of the insulation joint (43) extends to the interior of the socket (462), the inner wall of the sensor device (4) is provided with a partition plate (45), and an outer wall of the first thread line (412) is provided with a rotating circular ring (42).

11. The use method of the breakpoint detection device based on bi-directional detection according to claim 10, wherein the sensor device (4) is in a shape of a hollow column and is embedded in the buckle belt (1), the column plug (3) is cylindrical in shape, an outside dimension of the column plug (3) is equal to an inside dimension of the circular slot (2), the first gasket (7) and the second gasket (8) are disc-shaped in shape, the metal sheet (46) and the partition plate (45) are both disc-shaped, dimensions of the metal sheet (46) and the partition plate (45) are equal to an inside dimension of the sensor device (4), a side surface of the first plug (401) is fixedly connected with a wire (47) which penetrates through the round hole (441) of the baffle plate (44) and the lead wire port (461) of the metal sheet (46) and finally is led out through the first wire outlet (431) of the bottom cover (43), one end of the metal sheet (46) is also connected with a wire (47) which is led out through the second wire outlet (432) of the bottom cover (43).

12. The use method of the breakpoint detection device based on bi-directional detection according to claim 7, wherein an outer wall of each second support (14) is provided with a box (19), the box (19) comprises a relay (15), a digital potentiometer (16), a single-chip microcomputer (17) and a wireless transmission module (18), the relay (15), the digital potentiometer (16), the single-chip microcomputer (17) and the wireless transmission module (18) are all arranged inside the box (19) and electrically connected, and a heat emission hole (20) is formed in an outer wall of the box (19).
